(19) United States
(12) Patent Application Publication
(10) Pub. No.: US 2012/0153405 A1
(43) Pub. Date: Jun. 21, 2012

(54) Semiconductor Device Comprising a Contact Structure with Reduced Parasitic Capacitance

(75) Inventors: Jens Heinrich, Wachau (DE); Kai Frohberg, Niederau (DE); Torsten Huisinga, Dresden (DE); Ronny Pfuetzner, Dresden (DE)

(73) Assignee: GLOBALFOUNDRIES INC., Grand Cayman (KY)

(21) Appl. No.: 13/195,981

(22) Filed: Aug. 2, 2011

(30) Foreign Application Priority Data
Dec. 21, 2010 (DE) 10 2010 063 780.7

(51) Int. Cl. H01L 29/772; H01L 21/28

(52) U.S. Cl. 257/410; 438/586; 257/E21.19; 257/E29.242

(57) ABSTRACT

In sophisticated semiconductor devices, at least a portion of the interlayer dielectric material of the contact level may be provided in the form of a low-k dielectric material which may, in some illustrative embodiments, be accomplished on the basis of a replacement gate approach. Hence, superior electrical performance, for instance with respect to the parasitic capacitance, may be accomplished.

### BACKGROUND OF THE INVENTION

1. Field of the Invention

The present disclosure relates to the field of semiconductor manufacturing, and, more particularly, to the formation of an interconnect structure directly contacting a circuit element.

2. Description of the Related Art

Semiconductor devices, such as advanced integrated circuits, typically contain a very large number of circuit elements, such as transistors, capacitors, resistors and the like, which are usually formed in a substantially planar configuration on an appropriate substrate having formed thereon a crystalline semiconductor layer. Due to the large number of circuit elements and the required complex layout of modern integrated circuits, the electrical connections of the individual circuit elements may generally not be established within the same level on which the circuit elements are manufactured, but require one or more additional wiring layers, which are also referred to as metallization layers. These metallization layers generally include metal-containing lines, providing the inner-level electrical connection, and also include a plurality inter-level connections, which are also referred to as vias, that are filled with an appropriate metal and provide the electrical connection between two neighboring stacked metallization layers.

Due to the continuous reduction of the feature sizes of circuit elements in modern integrated circuits, the number of circuit elements for a given chip area, that is, the packing density, also increases, thereby requiring an even larger increase in the number of electrical connections to provide the desired circuit functionality, since the number of mutual connections between the circuit elements typically increases in an over-proportional way compared to the number of circuit elements. Therefore, the number of stacked metallization layers usually increases as the number of circuit elements per chip area becomes larger, while nevertheless the sizes of individual metal lines and vias are reduced. Due to the moderately high current densities that may be encountered during the operation of advanced integrated circuits, and owing to the reduced feature size of metal lines and vias, semiconductor manufacturers are increasingly replacing the well-known metallization materials, such as aluminum, by a metal that allows higher current densities and, hence, permits a reduction in the dimensions of the interconnections. Consequently, copper and alloys thereof are materials that are increasingly used in the fabrication of metallization layers due to the superior characteristics in view of resistance against electromigration and the significantly lower electrical resistivity compared to, for instance, aluminum. Despite these advantages, copper also exhibits a number of disadvantages regarding the processing and handling of copper in a semiconductor facility. For instance, copper readily diffuses in a plurality of well-established dielectric materials, such as silicon dioxide, wherein even minute amounts of copper, accumulating at sensitive device regions, such as contact regions of transistor elements, may lead to a failure of the respective device. For this reason, great efforts have to be made so as to reduce or avoid any copper contamination during the fabrication of the transistor elements, thereby rendering copper a less attractive candidate for the formation of contact plugs, which are in direct contact with respective contact regions of the circuit elements. The contact plugs or elements provide the electrical connection of the individual circuit elements to the first metallization layer, which is formed above an inter-layer dielectric material that encloses and passivates the circuit elements.

Consequently, in advanced semiconductor devices, the respective contact plugs or elements are typically formed of a tungsten-based metal in an inter-layer dielectric stack, typically comprised of silicon dioxide that is formed above a corresponding bottom etch stop layer, which may typically be formed of silicon nitride. Due to the ongoing shrinkage of feature sizes, however, the respective contact plugs have to be formed within respective contact openings with an aspect ratio which may be as high as approximately 8:1 or more, wherein a diameter of the respective contact openings may be 0.1 μm or even less for transistor devices of the 65 nm technology. The aspect ratio of such openings is generally defined as the ratio of the depth of the opening to the width of the opening. Consequently, the resistance of the respective contact plugs may significantly restrict the overall operating speed of highly advanced integrated circuits, even though a highly conductive material, such as copper or copper alloys, may be used in the metallization layers.

Moreover, complex lithography and patterning strategies have to be applied in order to form the contact openings with appropriate lateral dimensions so as to comply with the high packing density in the device level. When forming the contact level of the semiconductor device, typically one or more dielectric materials, such as silicon nitride, silicon dioxide and the like, are deposited on the basis of well-established deposition techniques and subsequently the resulting surface is to be planarized due to the pronounced surface topography generated by the gate electrode structures formed above the semiconductor layer. To this end, chemical mechanical polishing (CMP) techniques have proven to be viable process techniques so as to provide appropriate surface conditions for the subsequent performing of sophisticated lithography techniques. After patterning the contact openings, which may require an etch process for etching through the silicon dioxide material, possibly in combination with a silicon nitride material, which may frequently be used as an efficient etch stop material, contact openings are obtained which may connect to the gate electrode structures and to the contact areas in the active semiconductor regions. Thereafter, an appropriate contact metal, such as tungsten, is filled into the contact openings, followed by the removal of any excess material, which is also typically accomplished on the basis of CMP processes. Since the overall contact resistivity may represent a limiting factor for the overall electrical performance of sophisticated semiconductor devices, great efforts are being made in improving the process techniques, for instance reducing a thickness of any barrier or barrier material systems, which may typically have to be provided in combination with conventional chemical vapor deposition (CVD) recipes for providing the tungsten material. It turns out, however, that the barrier materials, which typically have a significantly reduced conductivity compared to the actual tungsten material, cannot be provided with arbitrarily reduced layer thickness values in order to ensure reliable coverage of any inner sidewall surface areas of the contact openings. Hence, many strategies have been developed in further improving the overall contact resistivity, for instance by appropriately designing the lateral dimensions of the contact plugs, for instance in the form of trenches and the like, wherein, however, any such structural redesigns may not necessarily be compliant with the overall device requirements. Furthermore, upon further device scaling, basically the same problems occur, irrespective of the lateral design of the contact elements. Consequently, it is very difficult to provide a reliable contact manufacturing flow for providing substantially planar surface conditions prior to performing the complex lithography and etch patterning regime, while at the same time superior integrity of the device level is to be guaranteed in view of chemical and mechanical resistivity, for instance with respect to unwanted copper diffusion into the device level from a copper-based metallization system, while also the contact resistivity is to be reduced.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to manufacturing techniques and semiconductor devices in which electrical performance of the contact level of sophisticated semiconductor devices may be enhanced by reducing the parasitic capacitance of the contact level. According to the principles disclosed herein, it has been recognized that the incorporation of a low-k dielectric material into the contact level of sophisticated semiconductor devices may provide a significant gain in performance compared to conventional contact levels, which are formed on the basis of silicon dioxide and silicon nitride. Generally, a low-k dielectric material, as is typically used in sophisticated metallization systems, is to be understood as a dielectric material having a dielectric constant of 3.0 and less, for example approximately 2.7 and less, wherein any such k values may be efficiently determined on the basis of well-established measurement techniques. In conventional strategies, the planarization of the conventional contact dielectric materials, such as silicon dioxide and silicon nitride, is accomplished on the basis of CMP techniques, while CMP is also used for removing any excess metal after filling the contact openings. To this end, the conventional dielectric materials have to provide superior mechanical characteristics in order to avoid undue defects in the dielectric material and in the sensitive device features, such as gate electrode structures, which are embedded in the dielectric material. Therefore, the incorporation of a low-k dielectric material into the contact level of sophisticated semiconductor devices has not been taken into consideration in conventional strategies. According to the principles disclosed herein, an appropriate configuration of the device may be implemented so as to provide integrity of the device level, for instance in terms of the mechanical stress applied to the device upon providing a substantially planar surface topography and in terms of avoiding undue copper penetration, while at the same time a significant portion of the dielectric material may be incorporated in the form of a low-k dielectric material, in particular at the interface connecting to the very first metallization layer. Consequently, as the metal lines of the first metallization layer may relatively deeply extend into the contact dielectric material so as to guarantee a reliable contact with the contact elements, the presence of a low-k dielectric material may result in a reduced parasitic capacitance. Similarly, the capacitance between the vertical contact elements may also be reduced, wherein, in particular, contact plugs with reduced lateral dimensions may be provided within the low-k dielectric material, thereby even further reducing any fringing capacitance with respect to the line-like structures, such as gate electrode structures formed in the device level. In some illustrative aspects disclosed herein, an appropriate configuration of the contact level may be efficiently obtained by applying a so-called replacement gate approach in which a placeholder material of a gate electrode structure is to be replaced at least with a highly conductive gate metal in the presence of a portion of the dielectric material of the contact level. In this case, an “intermediate” planarization step based on an appropriate dielectric material that laterally encloses the gate electrode structures has to be applied, thereby also providing the desired planar surface conditions for the further deposition of a low-k dielectric material, which may then be patterned in accordance with well-established process techniques without requiring the planarization of a pronounced surface topography, as is the case in conventional strategies.

One illustrative method disclosed herein comprises planarizing a dielectric layer of a semiconductor device so as to expose a surface of a placeholder material of a gate electrode structure. The method further comprises replacing the placeholder material at least with a conductive electrode material. Moreover, a first contact element is formed in the dielectric layer so as to connect to a semiconductor region. The method additionally comprises forming a low-k dielectric material above the dielectric layer and the gate electrode structure. Furthermore, a second contact element is formed in the low-k dielectric material so as to connect to the first contact element.

A further illustrative method disclosed herein relates to forming a semiconductor device. The method comprises planarizing a dielectric material formed above and laterally adjacent to a gate electrode structure that is formed above a semiconductor region. The method further comprises forming a contact element in the dielectric material so as to connect to a contact region of the semiconductor region. Furthermore, a low-k dielectric layer is formed above the dielectric material and a trench and a contact opening are formed in the low-k dielectric layer, wherein the contact opening connects to the contact element. More-over, the method comprises commonly filling the trench and the contact opening with a conductive material.

One illustrative semiconductor device disclosed herein comprises a gate electrode structure formed above a semiconductor region and a dielectric material layer that is formed above the semiconductor region. Moreover, the semiconductor device comprises a first contact element formed in the dielectric material layer so as to directly connect to a contact region formed in the semiconductor region. Additionally, the semiconductor device comprises a low-k dielectric layer formed above the dielectric material layer and a second contact element that is formed in the low-k dielectric layer and that connects to the first contact element. Moreover, the semiconductor device comprises a metallization layer comprising a metal line that directly connects to the second contact element.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1f schematically illustrate cross-sectional views of a semiconductor device during various manufacturing stages in forming a contact level of superior electrical performance on the basis of a low-k dielectric material in combination with a replacement gate approach, according to illustrative embodiments; and

FIGS. 1g-1h schematically illustrate cross-sectional views of the semiconductor device during various manufacturing stages in which a contact element is formed in a low-k dielectric material together with metal lines of a first metallization layer, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally contemplates semiconductor devices and manufacturing techniques in which superior electrical performance of the contact level may be achieved by incorporating a low-k dielectric material, for instance having a k value of 3.0 and less, while, in some illustrative embodiments, a k value of approximately 2.7 may be implemented on the basis of well-established low-k dielectric materials, such as hydrogen and carbon-containing silicon dioxide-based materials, also referred to as SiCOH materials, or any other low-k materials, such as polymer materials and the like. On the other hand, mechanical integrity and the required copper diffusion blocking effect may be guaranteed by providing any appropriate dielectric material, such as silicon nitride, possibly in combination with silicon dioxide, above the semiconductor material with a certain height level, for instance up to a height level that substantially corresponds to the height level of the gate electrode structures. In this manner, the planarization of the surface topography after the deposition of the conventional dielectric materials may be accomplished on the basis of CMP techniques, while the remaining interlayer dielectric material may be provided in the form of a low-k dielectric material on a planarized surface topography. In some illustrative embodiments, the planarization of the dielectric material having the superior mechanical and chemical resistivity may be accomplished in the context of forming sophisticated gate electrode structures, in which a placeholder material may be replaced at least with a highly conductive electrode metal, such as aluminum, possibly in combination with work function adjusting metal species and possibly in combination with a high-k dielectric material, so that a very efficient process flow may be implemented, in particular for sophisticated semiconductor devices requiring high-k metal gate electrode structures in combination with sophisticated contact levels due to reduced lateral dimensions of the transistor elements, wherein the incorporation of the low-k dielectric material may provide significant advantages by reducing the parasitic capacitance between the very first metallization layer and the contact level and also within the contact level and the device level.

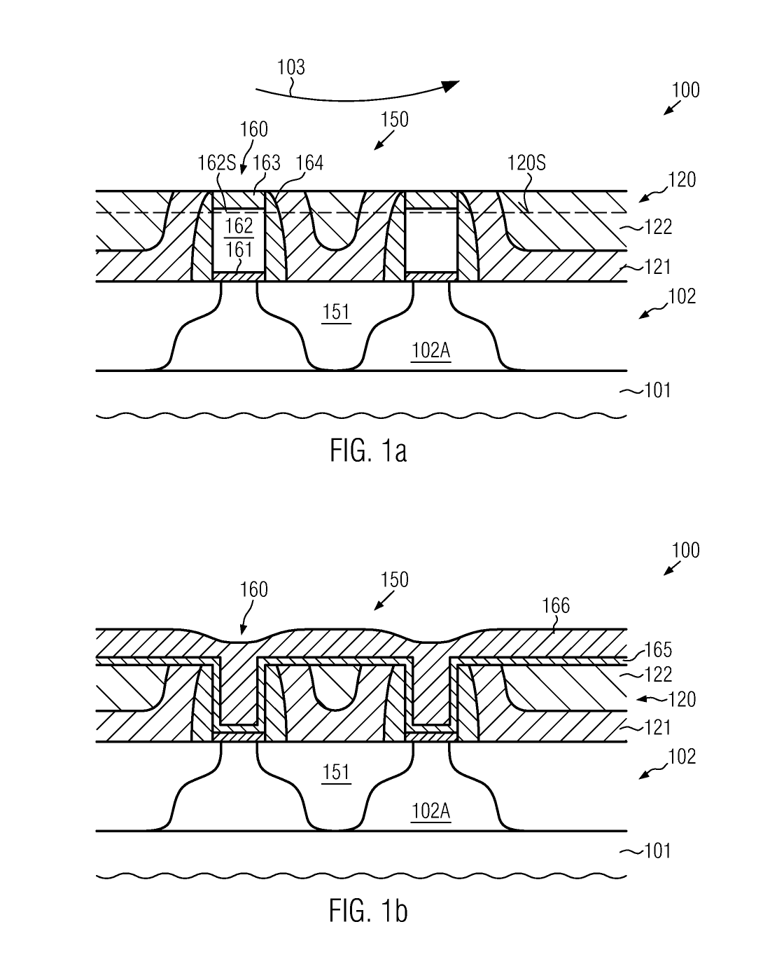

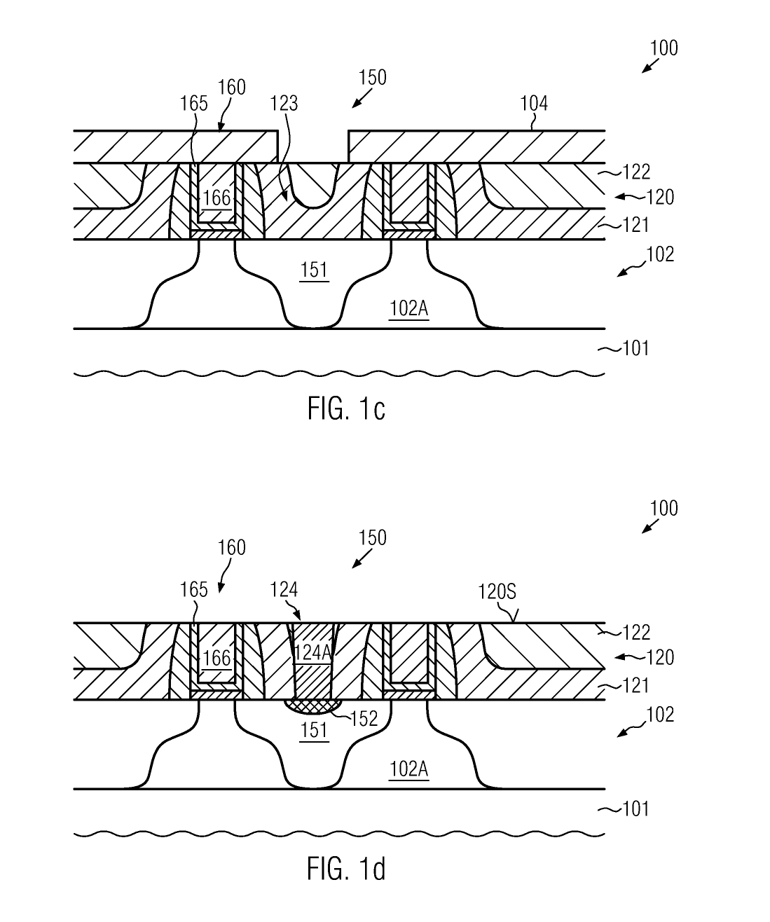

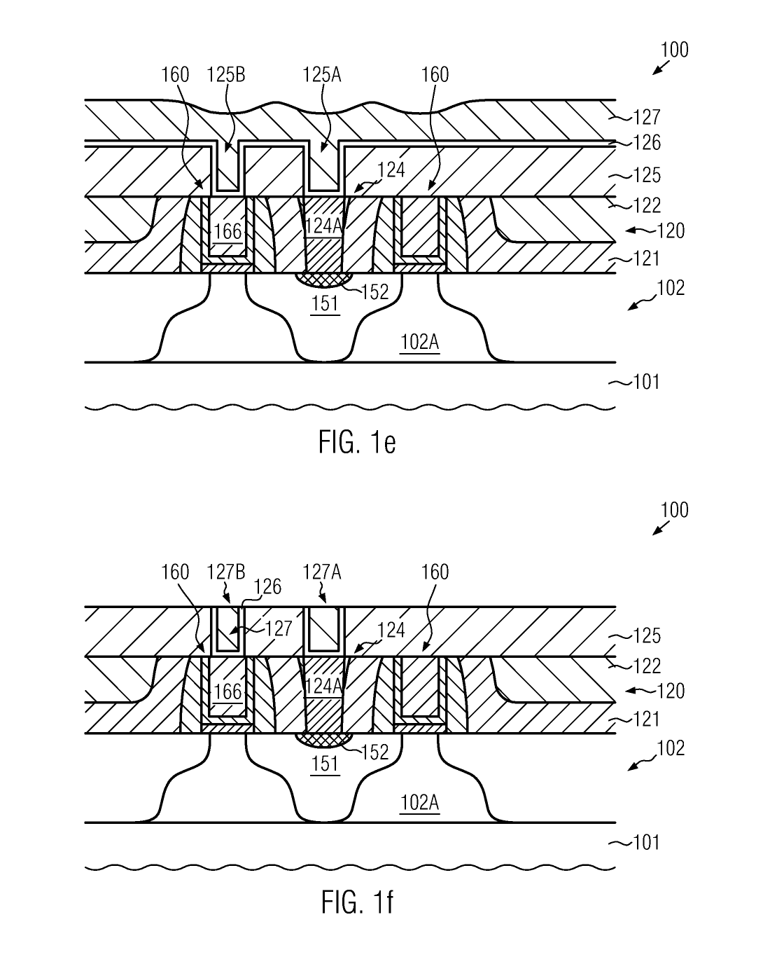

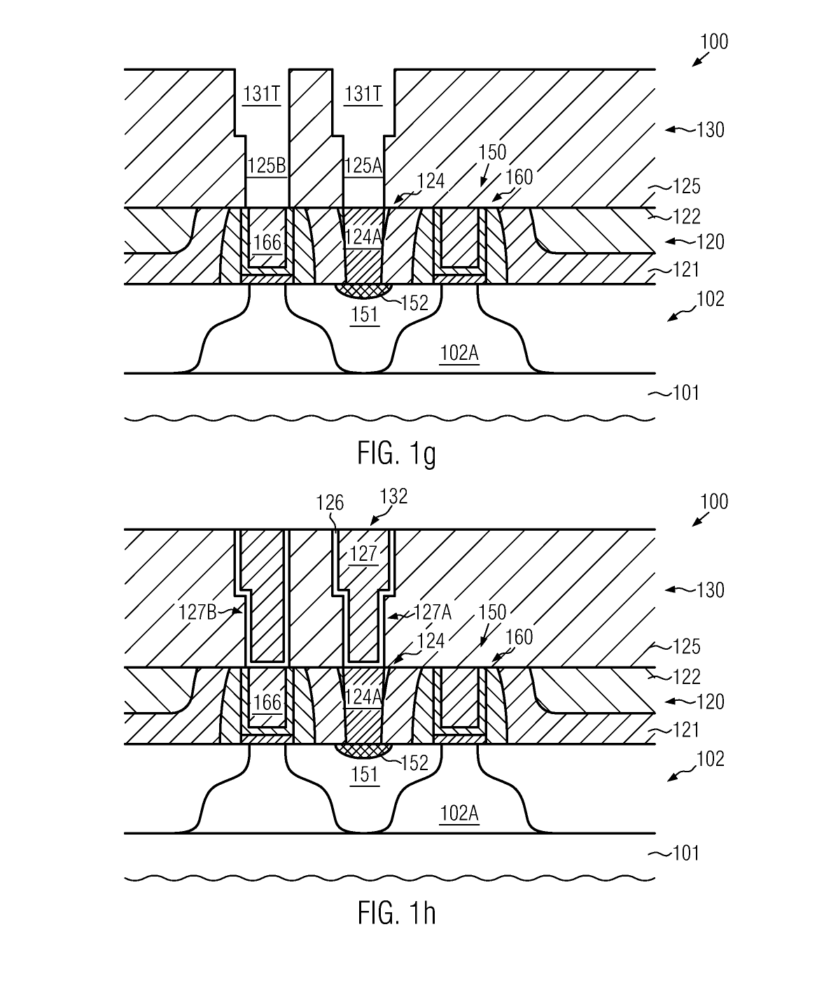

FIG. 1a schematically illustrates a cross-sectional view of a semiconductor device 100 in an advanced manufacturing stage. As illustrated, the semiconductor device 100 may comprise a substrate 101 and a semiconductor layer 102 formed above the substrate. The semiconductor layer 102 and the substrate 101 may form a silicon-on-insulator (SOI) architecture when a buried insulated material (not shown) is directly positioned below the semiconductor layer 102. In other cases, the semiconductor layer 102 may be a part of a crystalline material of the substrate 101. In the manufacturing stage shown, circuit elements 150, such as field effect transistors and the like, are formed in and above the semiconductor layer 102, that is, in and above a corresponding active region or semiconductor region 102A. The circuit elements 150 may thus comprise appropriate doped semiconductor areas in the active region 102A, as indicated as drain and source regions 151, when field effect transistors are considered. It should be appreciated that at least a portion of the doped regions 151 may also be denoted as contact regions, since at least a portion of these highly doped regions may have to be contacted by “vertical” contact elements, for instance contact plugs, contact bars and the like. Furthermore, the circuit elements 150 may comprise blind-like structures in illustrative embodiments provided in the form of gate electrode structures. To this end, a gate dielectric material 161, or a placeholder material, in combination with a further placeholder material 162, such as a silicon material, may be provided, possibly in combination with a dielectric cap layer 163 or cap layer system, which may be comprised of silicon nitride, silicon dioxide and the like. Moreover, typically, a sidewall spacer structure 164 may be provided in the gate electrode structures 160, for instance required for appropriately adjusting the dopant profiles of the regions 151 and the like. As discussed above, in sophisticated applications, critical dimensions of the circuit elements 150, such as a length of the gate electrode structures 160, i.e., in FIG. 1a, the horizontal extension of the placeholder material 162, may be 50 nm and less, wherein also a pitch between neighboring gate electrode structures 160 may be of comparable magnitude and may be approximately 100 nm and less.

Moreover, a portion of a contact level 120 may be provided, for instance in the form of a dielectric material 121, such as a silicon nitride material, in combination with a silicon dioxide material 122, which may represent a well-established dielectric material for forming the contact level of sophisticated semiconductor devices.

The semiconductor device 100 as illustrated in FIG. 1a may be formed in accordance with any appropriate process strategy. For example, the semiconductor or active region 102A may be formed by appropriately laterally delineating a semiconductor area in the layer 102 by providing isolation regions (not shown). Thereafter, appropriate materials may be provided, for instance in the form of a silicon dioxide base material for the dielectric layer 161 in combination with a silicon material and any dielectric materials for providing the cap layer 163. It should be appreciated that, in some approaches, a dielectric material 161 may comprise a high-k dielectric material, for instance in the form of a metal oxide, a metal oxide in combination with a silicon species and the like, in order to provide a high capacitive coupling, while at the same time keeping any gate leakage currents at an acceptable level. Next, sophisticated lithography and etch techniques may be applied so as to pattern the gate electrode structures 160 in accordance with the corresponding design rules. In a subsequent phase of the overall manufacturing flow, the doped regions 151 may be formed, for instance, by implantation, by incorporation of semiconductor material in a doped state and the like. At the same time, the spacer structure 164 may be completed and may be used, for instance, as an implantation mask for defining the lateral and dopant profile of the regions 151. After any high temperature processes, in some cases, the contact resistivity of the areas 151 may be reduced, for instance by incorporating a metal silicide, while in other cases a corresponding metal silicide may be provided in a later manufacturing stage.

Next, the layers 121 and 122 may be formed in accordance with well-established process strategies, wherein typically the material 121 may be provided in the form of a plasma enhanced CVD process, wherein, in some approaches, the material 121 may be provided in a highly stressed state so as to enhance performance of the transistors 150. Thereafter, the material layer 122 may be deposited based on sub-atmospheric CVD, high density plasma CVD, by using TEOS as a precursor material and the like. As previously explained, because of the pronounced surface topography caused by the gate electrode structures 160 and the reduced pitches, a planarization process has to be applied in the form of a CMP process, wherein the well-established materials 121, 122 may provide mechanical integrity of the gate electrode structures 160. As a part of the corresponding removal process or a separate planarization process 103 may be applied so as to increasingly remove materials of the layers 122, 121, thereby exposing the cap layers 163. Moreover, during the further advance of the removal process 103, a surface 120S of the contact level 120 may be lowered so as to eventually expose or form a surface 162S of the placeholder material 162. Consequently, after completing the removal process 103, a substantially planar surface 120S may be provided wherein the placeholder materials 162 are accessible via the exposed surface 162S. In this manufacturing stage, the placeholder material 162 may be removed, for instance, by applying well-established highly selective etch techniques, such as wet chemical etch processes, for instance using TMAH (tetra methyl ammonium hydroxide) and the like, while in other cases, additionally or alternatively to using wet chemical etch recipes, also plasma assisted etch techniques may be applied. In some illustrative embodiments, the corresponding removal process may be stopped in or on a dedicated conductive material layer (not shown), which may be applied together with the dielectric material 161, when the dielectric material 161 comprises a high-k dielectric material. In other embodiments, the removal process may be stopped on or within the dielectric layer 161, which may also be replaced or which may be completed by a high-k dielectric material, depending on the overall process strategy.

FIG. 1b schematically illustrates the device 100 in a further advanced manufacturing stage. As shown, at least a highly conductive gate metal 166, such as aluminum, may be formed above the contact level 120 and within the gate electrode structures 160. Furthermore, typically, the work function of the gate electrode structures 160 for the different types of transistors has to be appropriately adjusted, which typically requires the deposition of a specific work function metal, possibly in combination with conductive barrier materials and the like. To this end, a layer or layer system 165 may be deposited and an appropriate patterning sequence may be performed so as to provide the appropriate work function metal for the various types of gate electrode structures. To this end, well-established deposition techniques may be applied, such as sputter deposition, atomic layer deposition, CVD, electrochemical deposition techniques and the like. As discussed above, in some cases, also a high-k dielectric material may be deposited prior to forming the work function metal layer or layers 165. Thereafter, any excess material of the layers 166, 165, and possibly of any high-k materials, may be removed by performing an appropriate removal process, such as CMP, thereby also providing the required mechanical and chemical integrity of the circuit elements 150, since the dielectric materials 121, 122 may provide high mechanical stability and chemical resistivity since, for instance, silicon nitride is a very efficient copper diffusion blocking material, while, on the other hand, the fill metals 165, 166 may impart superior integrity to the gate electrode structures 160 together with superior electrical performance.

FIG. 1c schematically illustrates the device 100 in a further advanced manufacturing stage. As illustrated, the gate electrode structures 160 are laterally embedded in the dielectric material of a contact level 120 and are now provided as electrically isolated entities comprising the highly conductive electrode metal 166 in combination with the work function metal species 165, possibly comprising additional conductive barrier materials, and possibly in combination with a high-k dielectric material, as discussed above. Consequently, the contact level 120 in the current manufacturing stage may provide superior surface conditions for performing any further lithography and patterning processes. To this end, an etch mask 104 may be formed above the contact level 120 so as to define the lateral size and position of a contact opening 123 to be formed in the dielectric material of the contact level 120. To this end, any well-established lithography and patterning strategies may be applied, wherein the reduced height of the contact level 120, i.e., a height corresponding to the height of the gate electrode structures 160, may significantly reduce overall complexity of the corresponding patterning process since an additional part of the contact level 120 may still have to be formed by using a low-k dielectric material, as is also discussed above. Thus, upon forming the contact opening 123, the semiconductor region 151 may be exposed according to the lateral dimensions of the contact opening 123. In some illustrative embodiments, the doped region 151 may have formed therein a metal silicide (not shown), which may thus be exposed within the contact opening 123 and which may thus provide superior contact resistivity. In other illustrative embodiments, a corresponding metal silicide species may be formed through the contact opening 123, which may be accomplished by providing an appropriate refractory metal and initiating a silicidation process. Thereafter, or concurrently with forming a metal silicide, an appropriate contact material may be filled into the contact opening 123, which may be accomplished on the basis of well-established CVD techniques for forming tungsten material and the like. It should be appreciated that, if required, an additional barrier material or material system may be formed in the contact opening 123, if required. In other illustrative embodiments, the contact opening 123 may be filled with an appropriate metal, which may be deposited on the basis of electrochemical deposition techniques, such as electroless plating, wherein an appropriate catalyst material, such as a metal silicide material, may be provided at least in the exposed portion of the semiconductor region 151. For example, cobalt, although having a reduced conductivity compared to tungsten, may be efficiently formed on the basis of electrochemical deposition techniques, wherein the provision of any barrier material system may not be required, thereby achieving in total superior conductivity compared to a conventional tungsten/titanium/titanium nitride material system.

FIG. 1d schematically illustrates the semiconductor device 100 in a further advanced manufacturing stage. As illustrated, a contact element 124, such as a contact plug, a contact bar and the like, may be formed in the contact level 120 and may extend to a contact region 152, such as a metal silicide region provided in the doped semiconductor region 151. For example, the metal silicide 152 may be formed on the basis of the contact opening 123 (FIG. 1c), as discussed above, while in other cases the metal silicide 152 may be globally formed prior to depositing the dielectric materials of the contact level 120. Thus, the contact element 124 efficiently connects to the contact region 152 by means of the highly conductive core metal 124A, such as cobalt, tungsten and the like, wherein, if required, an additional barrier material system may be provided. Furthermore, in this manufacturing stage, the substantially planar surface topography 120S may still be provided after the removal of any excess material, which may have been deposited above the contact level 120 upon filling the contact opening 123 (FIG. 1c). Hence, mechanical and chemical integrity may be preserved by the materials 121 and 122, while at the same time the further processing may be continued on the basis of the superior surface topography 120S.

FIG. 1e schematically illustrates the semiconductor device 100 in a further advanced manufacturing stage according to illustrative embodiments in which the contact level 120 may be completed by providing a low-k dielectric material 125 above the previously provided materials 121, 122 and above the gate electrode structures 160 and the contact element 124. To this end, any well-established deposition techniques may be applied, such as CVD, spin-on techniques and the like, depending on the material characteristics of the low-k dielectric material 125. Due to the substantially planar surface topography, the layer 125 may be provided with a desired thickness without a further planarization in some illustrative embodiments, while in other cases a “mild” planarization process may be applied, if considered appropriate. The thickness of the layer 125 may be determined on the basis of the overall design rules in order to obtain the required critical distance with respect to a metallization system still to be formed above the contact level 120. It should be appreciated that a plurality of process techniques have been developed in the past so as to appropriately adjust the k value of the material 125. For example, the porosity of the material 125 may be adjusted by incorporating specific substances during the deposition of the material 125 and removing, at least to a certain degree, the corresponding substances by performing an appropriate treatment, such as a radiation treatment and the like. In this manner, a k value of approximately 2.7 or even less may be achieved on the basis of silicon dioxide-based materials. Thereafter, an appropriate patterning strategy may be applied, for instance by using a hard mask approach and the like, wherein well-established hard mask materials, such as titanium nitride and the like, may be applied and patterned so as to define the size and position of contact openings 125A, 125B. Moreover, the contact opening 125A is aligned so as to connect to the previously formed contact element 124, while the contact opening 125B may connect to a portion of the gate electrode structure 160. It should be appreciated that the contact openings 125A, 125B may have any appropriate lateral size and shape so as to correspond to the overall device requirements. For example, even if the circuit element 124 may be provided in the form of a contact bar that extends along a width direction, i.e., a direction perpendicular to the drawing plane of FIG. 1e, the contact opening 125A may be provided with a reduced lateral dimension in order to reduce the overall fringing capacitance of the resulting contact level. In other cases, the contact openings 125A may be provided in the form of trenches, if considered appropriate. Next, the contact openings 125A, 125B may be filled with a conductive material, such as a highly conductive copper material 127, in combination with a barrier material or material system 126, for instance in the form of tantalum, tantalum nitride and the like. In other cases, any other appropriate conductive fill metal may be used, for instance silver and the like, in order to even further enhance overall contact conductivity. In other cases, other contact materials may be used, such as tungsten and the like. The barrier layer 126, if provided, may be formed by applying well-established process techniques, such as sputter deposition, atomic layer deposition (ALD), CVD and the like, followed by the deposition of a seed material, if required, while in other cases the material 127 may be directly deposited on the barrier layer 126.

FIG. 1f schematically illustrates the semiconductor device 100 in a further advanced manufacturing stage in which isolated contact elements 127A, 127B are formed in the low-k dielectric material 125. To this end, any excess material may be removed, for instance by CMP, wherein, however, the conductive materials have to be removed without requiring a significant removal of dielectric material in order to planarize a surface topography thereof. For example, well-established CMP recipes may be applied for removing copper material from a low-k dielectric material in the presence of a barrier material system and subsequently removing the barrier material.

It should be appreciated that, if required, the mechanical characteristics of the low-k dielectric material 125 may be enhanced by performing a surface treatment prior to patterning the material 125 or by providing a thin silicon dioxide material and the like. Similarly, if required, an etch stop layer (not shown) may be formed prior to depositing the low-k dielectric material 125, if considered appropriate in view of patterning the material 125 and enhancing overall mechanical stability thereof. Furthermore, prior to depositing the materials 126, 127, additional surface treatments may be performed in order to reduce any patterning-related damage of the high-k dielectric material 125, for instance by applying appropriate “repair” chemicals, for instance in the form of HMDS (hexamethyldisilazane).

Thus, upon completing the contact level 120 by providing the low-k dielectric material 125 and the “vertical” contact elements 127A, 127B, the further processing may be continued by forming a metallization layer on the basis of any desired process strategy, wherein corresponding metal lines may connect to the contact elements 127A, 127B in accordance with the overall circuit layout. Moreover, due to the provision of the low-k dielectric material 125, a corresponding etching into the layer 125 upon reliably connecting any metal lines with the contact elements 127A, 127B, nevertheless a reduced overall parasitic capacitance may be achieved due to the superior dielectric characteristics of the material 125.

FIG. 1g schematically illustrates a cross-sectional view of the device 100 according to further illustrative embodiments in which the low-k dielectric material 125 may be provided with a sufficient thickness so as to correspond to the thickness of a first metallization layer 130. To this end, any appropriate deposition technique may be applied, wherein, if required, an etch stop layer (not shown) may be provided, possibly in combination with a surface layer (not shown) in order to enhance the overall mechanical stability of the dielectric material 125. Thereafter, any appropriate process strategy may be applied so as to form the contact openings 125A, 125B and corresponding trenches 131T of metal lines of the first metallization layer 130. To this end, the contact openings 125A, 125B may be formed first and thereafter an appropriate etch mask may be applied for defining the position and size of the trenches 131T. In other cases, the trenches 131T may be formed first and subsequently an additional patterning process may be applied so as to form the contact openings 125A, 125B. In still other cases, the contact openings 125A, 125B may be formed in a first portion of the low-k dielectric material 125 and subsequently these contact openings may be completed during a trench etch process in which concurrently the trenches 131T may be formed. Thereafter, if required, additional surface treatments may be performed, for instance in order to reduce etch related damage in the material 125, followed by the deposition of an appropriate barrier material, such as tantalum, tantalum nitride and a highly conductive core metal, such as copper, silver and the like. To this end, any well-established process techniques may be applied.

FIG. 1h schematically illustrates the device 100 in a further advanced manufacturing stage. As shown, the metallization layer 130 may comprise isolated metal lines 132, which may thus directly connect to contact elements 127A, 127B, which in turn may connect to the circuit elements 150, for example connecting to the contact element 124 and/or connecting to the gate electrode structures 160. It should be appreciated that, due to the common fill process for forming the highly conductive core metal 127, the metal lines 132 may “continuously” connect to the contact elements 127A, i.e., without forming a barrier material interface, thereby providing superior conductivity. Consequently, a second part of the contact level 120 in the form of the low-k dielectric material 125 and the contact elements 127A, 127B may be provided on the basis of a very efficient overall process flow since the first metallization layer 130 may be formed concurrently with the contact elements 127A, thereby obtaining superior alignment position and superior electrical performance due to higher conductivity and reduced parasitic capacitance.

As a result, the present disclosure provides semiconductor devices and manufacturing techniques in which a contact level may be formed partially on the basis of a low-k dielectric material, wherein a substantially planar surface topography may be obtained on the basis of well-established dielectric materials, which may be planarized down to a certain height level, for instance to a height level corresponding to the gate electrode structures so as to form therein contact elements that may directly connect to contact regions in the semiconductor layer. In some illustrative embodiments, the planarization of the first portion of the contact level may be achieved by concurrently exposing a placeholder material of a complex gate electrode structure, which may be subsequently replaced with at least a conductive electrode metal. In this manner, a superior surface topography may be available for the deposition of the low-k dielectric material in order to form a further vertical contact element in the low-k dielectric material or form the dielectric material system for a metallization layer in a common deposition process, which may subsequently be patterned so as to obtain the metal lines and the vertical contact elements in a common manufacturing sequence.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
planarizing a dielectric layer of a semiconductor device so as to expose a surface of a placeholder material of a gate electrode structure;
replacing said placeholder material at least with a conductive electrode material;
forming a first contact element in said dielectric layer so as to connect to a semiconductor region;
forming a low-k dielectric material above said dielectric layer and said gate electrode structure; and
forming a second contact element in said low-k dielectric material so as to connect to said first contact element.

2. The method of claim 1, further comprising forming a third contact element in said low-k dielectric layer so as to connect to said gate electrode structure.

3. The method of claim 1, wherein forming said first contact element comprises forming a first contact opening in said dielectric layer, filling said first contact opening with a first conductive material and removing an excess portion of said first conductive material by performing a planarization process.

4. The method of claim 3, wherein forming said second contact element comprises forming a second contact opening in said low-k dielectric layer and filling said second contact opening with a second conductive material that differs from said first conductive material.

5. The method of claim 4, wherein said second conductive material comprises at least one of copper, silver, tungsten and alloys thereof.

6. The method of claim 1, further comprising forming a dielectric material of a metallization layer above said dielectric layer and forming a metal line in said dielectric material so as to connect to said second contact element.

7. The method of claim 1, wherein forming said second contact element in said low-k dielectric layer comprises forming in said low-k dielectric layer a trench and a contact opening connected to the trench and commonly filling said contact opening and said trench with a conductive material.

8. The method of claim 7, further comprising forming a further contact opening so as to connect to said gate electrode structure and commonly filling said contact opening, said further contact opening and said trench with said conductive material.

9. The method of claim 7, wherein gate electrode structure has a gate length of 50 nm or less.

10. The method of claim 9, wherein said gate electrode structure comprises a high-k dielectric material.

11. A method of forming a semiconductor device, the method comprising:
planarizing a dielectric material formed above and laterally adjacent to a gate electrode structure formed above a semiconductor region;
forming a contact element in said dielectric material so as to connect to a contact region of said semiconductor region;
forming a low-k dielectric layer above said dielectric material;
forming a trench and a contact opening in said low-k dielectric layer, said contact opening connecting to said contact element; and
commonly filling said trench and said contact opening with a conductive material.

12. The method of claim 11, wherein commonly filling said trench and said contact opening with a conductive material comprises depositing at least one of copper and silver.

13. The method of claim 11, wherein forming said contact element comprises forming an opening in said dielectric material so as to expose a portion of said contact region and forming at least one of tungsten and cobalt in said opening.

14. The method of claim 11, further comprising forming a second contact element in said dielectric material so as to connect to an electrode material of said gate electrode structure.

15. The method of claim 11, wherein planarizing said dielectric material comprises exposing a surface of a placeholder material of said gate electrode structure and wherein said method further comprises replacing said placeholder material with at least an electrode metal.

16. A semiconductor device, comprising:
a gate electrode structure formed above a semiconductor region;
a dielectric material layer formed above said semiconductor region;
a first contact element formed in said dielectric material layer so as to directly connect to a contact region formed in said semiconductor region;
a low-k dielectric layer formed above said dielectric material layer;
a second contact element formed in said low-k dielectric layer and connecting to said first contact element; and
a metallization layer comprising a metal line that directly connects to said second contact element.

17. The semiconductor device of claim 16, wherein said first contact element comprises at least one of tungsten and cobalt.

18. The semiconductor device of claim 17, wherein said second contact element comprises at least one of copper and silver.

19. The semiconductor device of claim 18, wherein said gate electrode structure comprises a high-k dielectric material and an electrode metal.

20. The semiconductor device of claim 16, wherein said metal line directly connects to said second vertical contact element without forming an intermediate interface comprised of a barrier material.
